(19) United States
(12) Patent Application Publication
(10) Pub. No.: US 2026/0142655 A1
(43) Pub. Date: May 21, 2026

(54) SEMICONDUCTOR DEVICE

(71) Applicant: Mitsubishi Electric Corporation, Tokyo (JP)

(72) Inventor: Mitsuru KANEDA, Tokyo (JP)

(73) Assignee: Mitsubishi Electric Corporation, Tokyo (JP)

(21) Appl. No.: 19/326,668

(22) Filed: Sep. 11, 2025

(30) Foreign Application Priority Data
Nov. 18, 2024 (JP) 2024-200884

(51) Int. Cl. H03K 17/082

(52) U.S. Cl. CPC H03K 17/082; H03K 2217/0027

(57) ABSTRACT

An object is to provide a technique capable of appropriately setting a semiconductor switching element. A semiconductor device includes a control circuit obtaining main current using a correlation between sense voltage and the main current and determining whether or not the main current exceeds a threshold value, wherein in the correlation, when one of the sense voltage and the main current gets large, another one thereof non-linearly gets large, and a ratio of change of the main current to the sense voltage in a case where the sense voltage is larger than predetermined voltage is smaller than the ratio in a case where the sense voltage is smaller than the predetermined voltage.

### BACKGROUND

### Technical Field

The present disclosure relates to a semiconductor device.

### Description of the Background Art

Proposed recently is a semiconductor device protecting an operation of a semiconductor switching element based on sense voltage of a semiconductor switching element (for example, International Publication No. 2015/033449). Also proposed is that an OC threshold value for protecting a semiconductor switching element in overcurrent and an SC threshold value for protecting a semiconductor switching element in short circuit are set to sense voltage. In this case, the OC threshold value and the SC threshold value are set to be different from each other by a constant value based on a premise that a proportional relationship is established between the sense voltage and main current of the semiconductor switching element.

### SUMMARY

However, a relationship between the sense voltage and the main current is not the proportional relationship but is a non-linear relationship depending on a circuit to which the semiconductor switching element is connected in some cases. When the OC threshold value and the SC threshold value are set as described above based on the premise that the proportional relationship is established in such a case, there is a problem that both the main current corresponding to the OC threshold value and the main current corresponding to the SC threshold value cannot be appropriately set.

The present disclosure therefore has been made to solve the above problems, and it is an object to provide a technique capable of appropriately setting a semiconductor switching element.

A semiconductor device according to the present disclosure includes: a semiconductor switching element including a main terminal in which main current flows and a sense terminal in which sense current having a correlation with the main current flows; a voltage generation circuit made up of only a passive element and generating sense voltage based on the sense current; and a control circuit obtaining the main current corresponding to the sense voltage which has been generated using a correlation between the sense voltage and the main current and determining whether or not the main current exceeds a threshold value, wherein in the correlation, when one of the sense voltage and the main current gets large, another one of the sense voltage and the main current non-linearly gets large, and a ratio of change of the main current to the sense voltage in a case where the sense voltage is larger than predetermined voltage is smaller than the ratio in a case where the sense voltage is smaller than the predetermined voltage.

The semiconductor switching element can be appropriately set.

These and other objects, features, aspects and advantages of the present disclosure will become more apparent from the following detailed description of the present disclosure when taken in conjunction with the accompanying diagrams.

### BRIEF DESCRIPTION OF THE DRAWINGS

FIG. 1 is a circuit diagram illustrating a configuration of a semiconductor device according to an embodiment 1.

FIG. 2 is a diagram illustrating a correlation between sense voltage and main current in a case where a resistance value of resistance RS is relatively low.

FIG. 3 is a diagram illustrating a correlation between the sense voltage and the main current in a case where a resistance value of the resistance RS is relatively high.

FIG. 4 is a circuit diagram illustrating a part of the configuration of the semiconductor device according to the embodiment 1.

FIG. 5A and FIG. 5B are diagrams each illustrating a waveform of sense current and the main current in a case where a resistance value of the resistance RS is relatively low.

FIG. 6A and FIG. 6B are diagrams each illustrating a waveform of the sense current and the main current in a case where a resistance value of the resistance RS is relatively high.

FIG. 7 is a diagram for explaining an operation of a related device.

FIG. 8 is a circuit diagram illustrating a configuration of a semiconductor device according to a modification example.

### DESCRIPTION OF THE PREFERRED EMBODIMENTS

Embodiments are described with reference to the appended diagrams hereinafter. Features described in each embodiment described below is exemplification, thus all features are not necessarily applied. The same or similar reference numerals will be assigned to similar constituent elements in a plurality of embodiments in the description hereinafter, and the different constituent elements are mainly described hereinafter.

### Embodiment 1

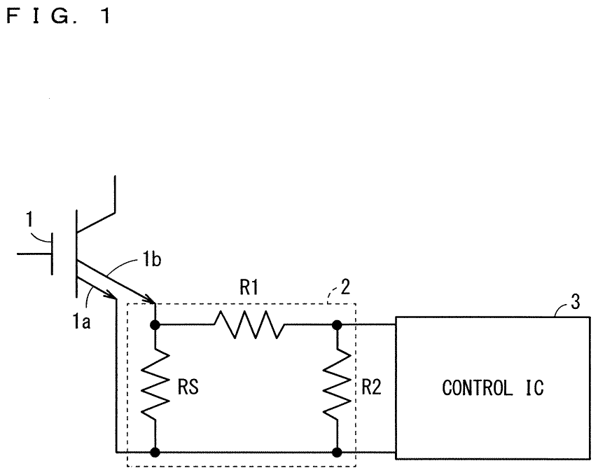

FIG. 1 is a circuit diagram illustrating a configuration of a semiconductor device according to the present embodiment 1. The semiconductor device in FIG. 1 includes a semiconductor switching element 1, a voltage generation circuit 2, and a control IC 3 as a control circuit.

The semiconductor switching element 1 includes a main terminal 1a in which main current flows and a sense terminal 1b in which sense current flows, and the sense current has a correlation with the main current. The semiconductor switching element 1 includes a main switching element having a main terminal 1a and a sense switching element having a sense terminal 1b as described hereinafter. Since the main switching element and the sense switching element have substantially the same configuration other than a circuit scale, the sense current flowing in the sense terminal 1b has a correlation with the main current flowing in the main terminal 1a.

The semiconductor switching element 1 is a metal oxide semiconductor field effect transistor (MOSFET), an insulated gate bipolar transistor (IGBT), and a reverse conducting IGBT (RC-IGBT), for example. The semiconductor switching element 1 may be composed of typical silicon (Si), or may be composed of a wide bandgap semiconductor such as silicon carbide (SiC), gallium nitride (GaN), gallium oxide (Ga₂O₃), or diamond. When the semiconductor switching element 1 is composed of a wide bandgap semiconductor, a stable operation at high temperatures and high voltage and increased switching speed of the semiconductor device can be achieved.

The voltage generation circuit 2 does not include an active element such as an operational amplifier but is made up of only a passive element, and generates sense voltage based on the sense current flowing in the sense terminal 1b. In the present embodiment 1, the passive element of the voltage generation circuit 2 includes resistance RS as first resistance, resistance R1 as second resistance, and resistance R2 as third resistance.

One end of the resistance RS and one end of the resistance R1 are connected to the sense terminal 1b. The resistance R2 is connected to the other end of the resistance RS and the other end of the resistance R1, and the other end of the resistance RS is connected to the main terminal 1a. A resistance value of the resistance RS is equal to or larger than 100Ω, for example. Resistance values of the resistance R1 and the resistance R2 are large enough so that the sense current does not substantially flow in the resistance R1 and the resistance R2, and are tens of times as large as the resistance value of the resistance R2 or more, for example.

The voltage generation circuit 2 according to the present embodiment 1 having the above configuration generates voltage of the resistance R2 as the sense voltage. Since the sense voltage is substantially proportional to the sense current and the sense current has a correlation with the main current as described above, the sense voltage has a correlation with the main current.

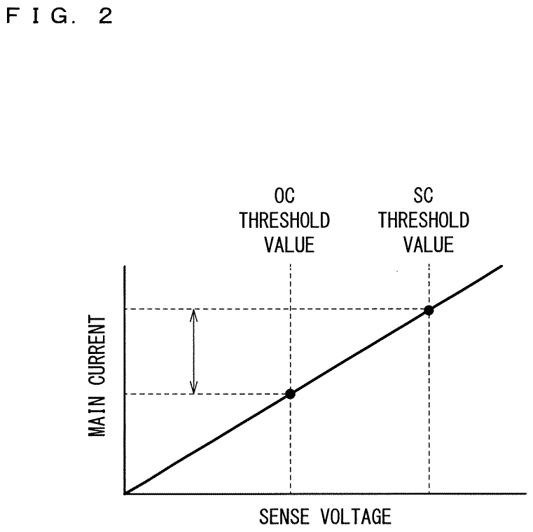

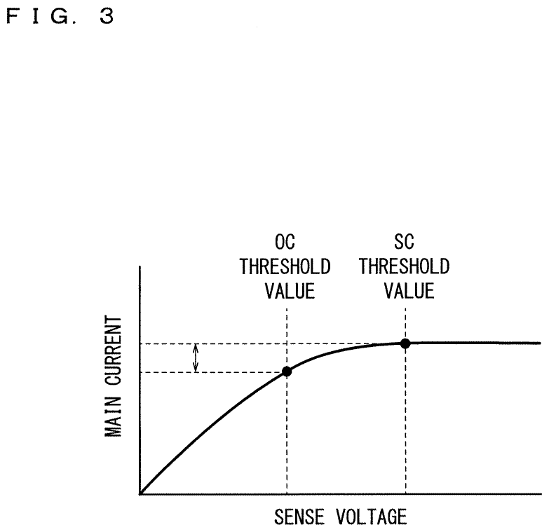

Herein, in the configuration that the semiconductor switching element 1 is connected to the voltage generation circuit 2 illustrated in FIG. 1 and the resistance value of the resistance RS of the voltage generation circuit 2 is relatively low, the correlation between the sense voltage and the main current has substantially the proportional relationship as illustrated in FIG. 2. In the meanwhile, in the configuration that the semiconductor switching element 1 is connected to the voltage generation circuit 2 illustrated in FIG. 1 and the resistance value of the resistance RS of the voltage generation circuit 2 is relatively high such as 100Ω or more, for example, the correlation between the sense voltage and the main current has the non-linear relationship as illustrated in FIG. 3. This reason is described hereinafter.

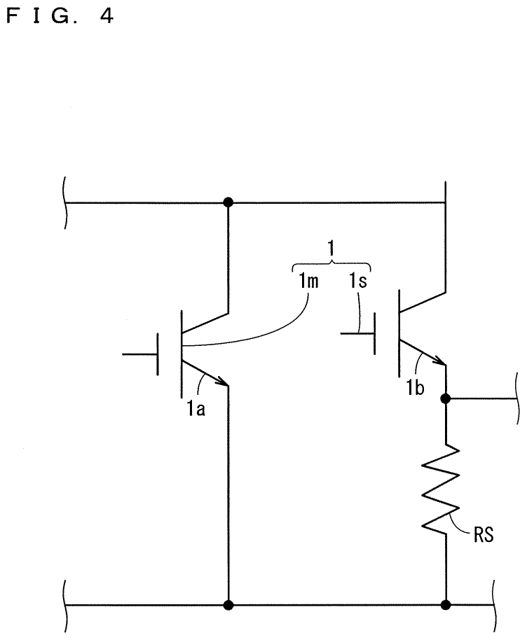

FIG. 4 is a circuit diagram illustrating a connection relationship between a main switching element 1m and a sense switching element 1s included in the semiconductor switching element 1 and the resistance RS. Established in the configuration in FIG. 4 is a relational expression of ON voltage of the main switching element 1m=ON voltage of the sense switching element 1s+the resistance RS×the sense current. The ON voltage herein is source-drain voltage or emitter-collector voltage.

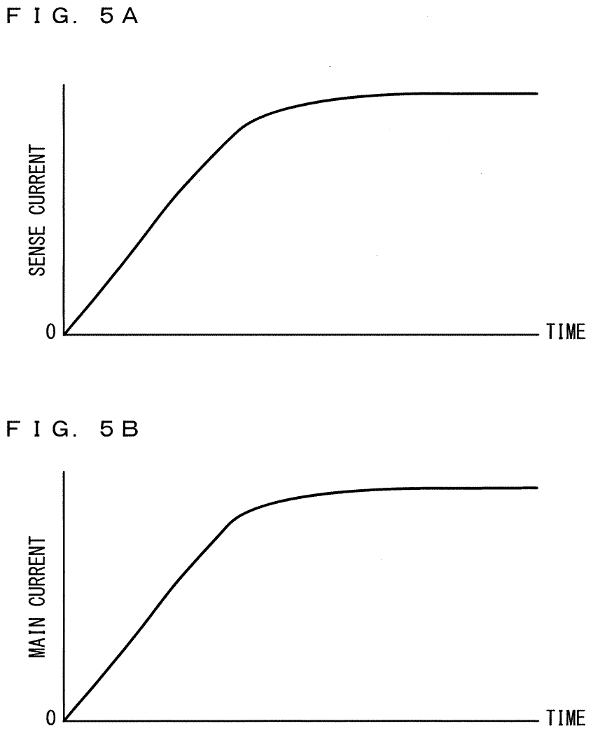

When the resistance value of the resistance RS is relatively low, voltage corresponding to the resistance RS×the sense current is sufficiently smaller than the ON voltage of the main switching element 1m. Thus, the sense current is not limited by the ON voltage of the main switching element 1m in the above relational expression. Thus, the waveform of the sense current in FIG. 5A in the case where the resistance value of the resistance RS is relatively low is almost similar to that of the main current in FIG. 5B.

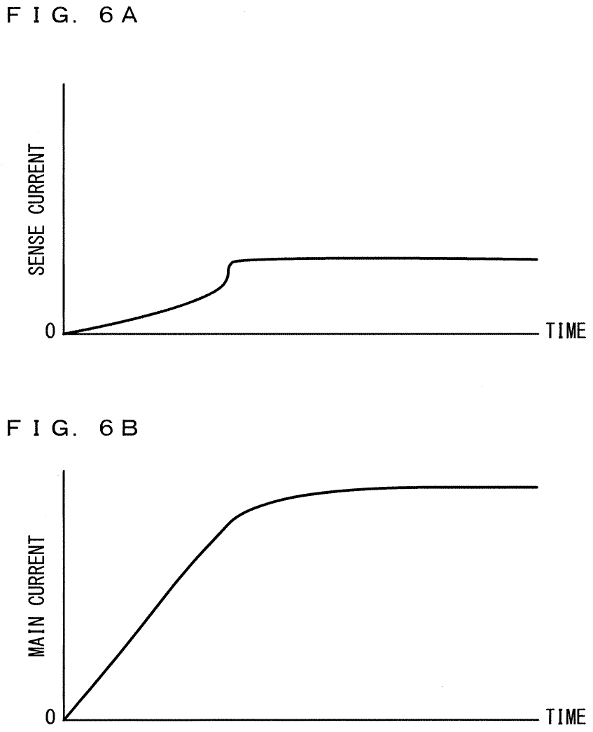

In the meanwhile, when the resistance value of the resistance RS is relatively high, voltage corresponding to the resistance RS×the sense current cannot exceed the ON voltage of the main switching element 1m in the above relational expression. Thus, the sense current immediately after the main switching element 1m is switched on is limited to the ON voltage. After a moment, when the main current of the main switching element 1m is saturated, the ON voltage of the main switching element 1m rapidly increases, and the sense current also increases rapidly. Thus, the waveform of the sense current in FIG. 6A in the case where the resistance value of the resistance RS is relatively high is not similar to that of the main current in FIG. 6B.

As a result described above, when the resistance value of the resistance RS is relatively low, the correlation between the sense voltage and the main current is substantially the proportional relationship as illustrated in FIG. 2. However, when the resistance value of the resistance RS is relatively high, the correlation between the sense voltage and the main current is the non-linear relationship as illustrated in FIG. 3.

Since the resistance value of the resistance RS is relatively high in the present embodiment 1, the control IC 3 obtains the main current corresponding to the sense voltage generated in the voltage generation circuit 2 using the correlation as illustrated in FIG. 3. That is to say, when one of the sense voltage and the main current gets large, the other one thereof non-linearly gets large, and used for the control IC 3 is the correlation that a ratio of change of the main current to the sense voltage in the case where the sense voltage is larger than predetermined voltage is smaller than a ratio in the case where the sense voltage is smaller than the predetermined voltage.

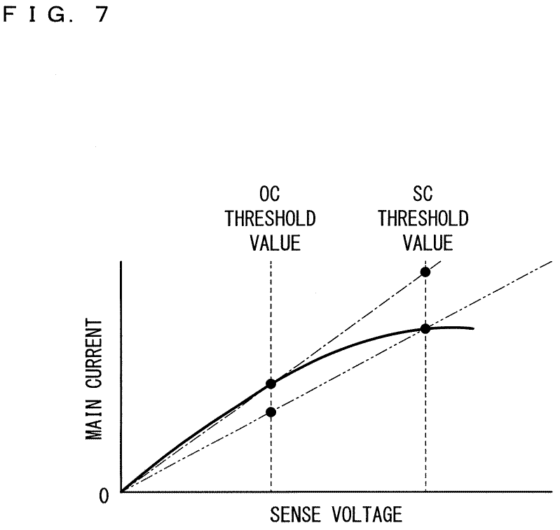

A related device relating to the semiconductor device according to the present embodiment 1 is described next using FIG. 7. FIG. 7 is a diagram for explaining an operation of the related device. In the related device, the OC threshold value for protection in overcurrent and the SC threshold value for protection in short circuit are set to the sense voltage to be different from each other by a constant value based on a premise that a proportional relationship is established between the main current and the sense voltage.

However, when the main current corresponding to the OC threshold value is appropriately set as with a dash-dotted line in FIG. 7 in the above configuration that the correlation between the sense voltage and the main current is the non-linear relationship, the main current corresponding to the SC threshold value cannot be appropriately set. In this case, short circuit cannot be protected in a condition where the short circuit should be protected. In the meanwhile, when the main current corresponding to the SC threshold value is appropriately set as with a dash-double-dot line in FIG. 7, the main current corresponding to the OC threshold value cannot be appropriately set. In this case, protection of the overcurrent is performed in a condition where protection of the overcurrent needs not be performed.

In the meanwhile, in the present embodiment 1, the control IC 3 obtains the main current corresponding to the sense voltage generated in the voltage generation circuit 2 using the correlation as illustrated in FIG. 3, and determines whether or not the main current exceeds the threshold value. Since the correlation corresponding to a solid line in FIG. 7 can be used, the main current corresponding to the OC threshold value and the main current corresponding to the SC threshold value can be appropriately set when the OC threshold value and the SC threshold value are set to have the values different from each other by a constant value, for example. That is to say, setting for protecting the semiconductor switching element 1 can be appropriately performed.

Since the voltage generation circuit 2 is made up of only the passive element in the present embodiment 1, the configuration that the correlation between the sense voltage and the main current is the non-linear relationship can be easily achieved.

### Modification Example

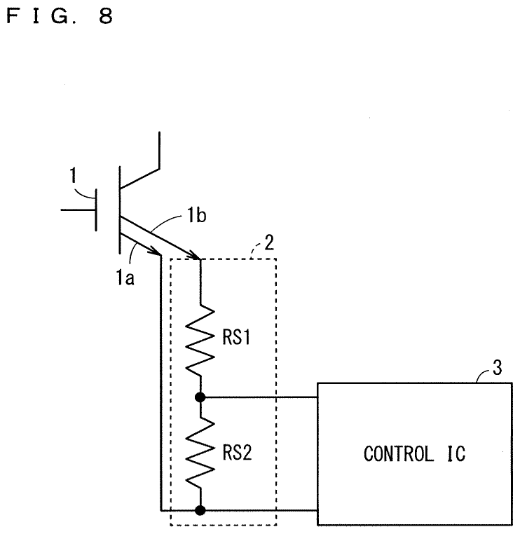

Although the passive element of the voltage generation circuit 2 includes the resistance RS, the resistance R1, and the resistance R2 in the embodiment 1, this configuration is not necessary. For example, as with FIG. 8, the passive element of the voltage generation circuit 2 may include resistance RS1 as first resistance and resistance RS2 as second resistance.

One end of the resistance RS1 is connected to the sense terminal 1b, one end of the resistance RS2 is connected to the other end of the resistance RS1, and the other end of the resistance RS2 is connected to the main terminal 1a. A total value of a resistance value of the resistance RS1 and a resistance value of the resistance RS2 is equal to or larger than 100Ω, and the voltage generation circuit 2 generates voltage of the resistance R2 as sense voltage.

In such a configuration, since the total value of the resistance value of the resistance RS1 and the resistance value of the resistance RS2 is relatively high, the waveform of the sense current is not similar to that of the main current, and the correlation between the sense voltage and the main current is the non-linear relationship.

In the meanwhile, the control IC 3 according to the present modification example obtains the main current corresponding to the sense voltage generated in the voltage generation circuit 2 using the correlation as illustrated in FIG. 3 in the manner similar to the embodiment 1, and determines whether or not the main current exceeds the threshold value. According to such a configuration, setting for protecting the semiconductor switching element 1 can be appropriately performed in the manner similar to the embodiment 1. Since the voltage generation circuit 2 is made up of only the passive element, the configuration that the correlation between the sense voltage and the main current is the non-linear relationship can be easily achieved in the manner similar to the embodiment 1.

In the present disclosure in English, “a” and “an” indicates one or more matters. Thus, “a”, “an”, “one or more”, and “at least one” can be used in the same sense.

Each embodiment and each modification example can be arbitrarily combined, or each embodiment and each modification can be appropriately varied or omitted.

The aspects of the present disclosure are collectively described hereinafter as appendixes.

### APPENDIX 1

A semiconductor device, comprising:
a semiconductor switching element including a main terminal in which main current flows and a sense terminal in which sense current having a correlation with the main current flows;
a voltage generation circuit made up of only a passive element and generating sense voltage based on the sense current; and
a control circuit obtaining the main current corresponding to the sense voltage which has been generated using a correlation between the sense voltage and the main current and determining whether or not the main current exceeds a threshold value, wherein
in the correlation,
   when one of the sense voltage and the main current gets large, another one of the sense voltage and the main current non-linearly gets large, and
   a ratio of change of the main current to the sense voltage in a case where the sense voltage is larger than predetermined voltage is smaller than the ratio in a case where the sense voltage is smaller than the predetermined voltage.

### APPENDIX 2

The semiconductor device according to Appendix 1, wherein
the passive element includes:
first resistance having one end connected to the sense terminal;
second resistance having one end connected to the sense terminal and a resistance value larger than the first resistance; and
third resistance connected between another end of the first resistance and another end of the second resistance and having a resistance value larger than the first resistance, and
the sense voltage is voltage of the third resistance.

### APPENDIX 3

The semiconductor device according to Appendix 2, wherein
a resistance value of the first resistance is equal to or larger than 100Ω.

### APPENDIX 4

The semiconductor device according to Appendix 1, wherein
the passive element includes:
first resistance having one end connected to the sense terminal; and
second resistance connected to another end of the first resistance, and
the sense voltage is voltage of the second resistance.

### APPENDIX 5

The semiconductor device according to Appendix 4, wherein
a total value of a resistance value of the first resistance and a resistance value of the second resistance is equal to or larger than 100Ω.

While the disclosure has been shown and described in detail, the foregoing description is in all aspects illustrative and not restrictive. It is therefore understood that numerous modifications and variations can be devised.

What is claimed is:

1. A semiconductor device, comprising:
a semiconductor switching element including a main terminal in which main current flows and a sense terminal in which sense current having a correlation with the main current flows;
a voltage generation circuit made up of only a passive element and generating sense voltage based on the sense current; and
a control circuit obtaining the main current corresponding to the sense voltage which has been generated using a correlation between the sense voltage and the main current and determining whether or not the main current exceeds a threshold value, wherein
in the correlation,
when one of the sense voltage and the main current gets large, another one of the sense voltage and the main current non-linearly gets large, and
a ratio of change of the main current to the sense voltage in a case where the sense voltage is larger than predetermined voltage is smaller than the ratio in a case where the sense voltage is smaller than the predetermined voltage.

2. The semiconductor device according to claim 1, wherein
the passive element includes:
first resistance having one end connected to the sense terminal;
second resistance having one end connected to the sense terminal and a resistance value larger than the first resistance; and
third resistance connected between another end of the first resistance and another end of the second resistance and having a resistance value larger than the first resistance, and
the sense voltage is voltage of the third resistance.

3. The semiconductor device according to claim 2, wherein
a resistance value of the first resistance is equal to or larger than 100Ω.

4. The semiconductor device according to claim 1, wherein
the passive element includes:
first resistance having one end connected to the sense terminal; and
second resistance connected to another end of the first resistance, and
the sense voltage is voltage of the second resistance.

5. The semiconductor device according to claim 4, wherein
a total value of a resistance value of the first resistance and a resistance value of the second resistance is equal to or larger than 100Ω.
